(19) United States
(12) Patent Application Publication
(10) Pub. No.: US 2026/0073095 A1
(43) Pub. Date: Mar. 12, 2026

(54) METHOD AND SYSTEM FOR DESIGNING MOBILITY POINTS BASED ON TIME-SERIES ANALYSIS

(71) Applicant: LBS TECH INC., Incheon (KR)

(72) Inventor: Si Wan LEE, Incheon (KR)

(73) Assignee: LBS TECH INC., Incheon (KR)

(21) Appl. No.: 19/391,987

(22) Filed: Nov. 17, 2025

(30) Foreign Application Priority Data
Oct. 28, 2025 (KR) 10-2025-0158233

(51) Int. Cl. G06F 30/20

(52) U.S. Cl. CPC G06F 30/20

(57) ABSTRACT

The present invention relates to a method and system for designing mobility points (MPs) that support boarding, alighting, and transfers between various modes of transportation by performing time-series analysis on transportation, walking, and environmental data, and for visually providing the design results, thereby improving the mobility convenience of all users including mobility-vulnerable persons.

### CROSS-REFERENCE TO RELATED APPLICATION(S)

This application claims the priority benefit of Korean Patent Application No. 10-2025-0158233, filed on Oct. 28, 2025, in the Korean Intellectual Property Office, the disclosure of which is incorporated herein by reference.

### BACKGROUND

### 1. Field of the Invention

The present invention relates to a method and system for designing mobility points (MPs) based on time-series analysis, and more particularly, to a technology for designing a mobility point (MP) that supports boarding, alighting, and transfers between various means of transportation by performing time-series analysis on transportation, walking, and environmental data, and for visually providing the design results, thereby improving the mobility convenience of all users, including mobility-vulnerable persons.

### 2. Description of the Related Art

Recently, urban transportation environments have become increasingly complex due to the coexistence of various means of transportation, such as buses, subways, taxis, and autonomous shuttles. Accordingly, numerous navigation services and traffic information systems have been developed to optimize travel routes or support transfers between public transportation modes.

However, conventional technologies have primarily focused on calculating the shortest-distance or minimum-time routes based on vehicle-oriented traffic data or static map information. Such approaches have limitations in sufficiently reflecting actual pedestrian environments or the variability of traffic and walking conditions over time.

In particular, for mobility-vulnerable persons (such as visually impaired persons, persons with physical disabilities, hearing-impaired persons, and elderly persons), the accessibility of boarding or alighting points along a route between a departure point and a destination directly affects their mobility convenience. Conventional route guidance technologies, however, have failed to comprehensively consider user-specific conditions, such as ramps, tactile paving, walkway width, or illumination.

Furthermore, although real-time traffic and walking data have recently become available, existing systems still calculate routes based on data from a single point in time. These systems lack functionality to predict or design boarding and alighting points by reflecting temporal changes—such as weather, time of day, or day of the week-through time-series pattern analysis.

### SUMMARY

An object of the present invention is to establish a smart pedestrian environment in which all pedestrians can move smoothly, and to improve the mobility convenience of users by optimizing transfer and travel routes among various means of transportation centered on a mobility point (MP).

Another object of the present invention is to continuously improve the operational status of a mobility point (MP) through the collection and time-series analysis of real-time dynamic data, and to enhance the accuracy and reliability of pedestrian navigation services by utilizing an appropriateness evaluation procedure.

A further object of the present invention is to provide a technology capable of implementing a sustainable mobility infrastructure that can be continuously expanded within a city by establishing standardized guidelines for building mobility points (MPs) and linking the system with an urban real-time traffic control system.

However, the technical problems to be solved by the present invention are not limited to the above-mentioned ones, and various modifications may be made without departing from the spirit and scope of the present invention.

In accordance with an embodiment of the present invention, there is provided a method for designing mobility points based on time-series analysis, performed by a computer device including at least one processor, the method comprising:
receiving, from a user terminal, one of a departure point and a destination;
collecting pedestrian environment data relating to traffic, walking, and environment for a surrounding area of the received location and dynamic data reflecting variation patterns accumulated over time;
deriving, through time-series analysis based on the pedestrian environment data and the dynamic data, optimal pick-up and drop-off points within the surrounding area; and
visualizing the derived points and displaying them on the user terminal.

In accordance with another embodiment of the present invention, there is provided a system for designing mobility points based on time-series analysis, the system comprising:
a receiver configured to receive, from a user terminal, one of a departure point and a destination;
a data collection unit configured to collect pedestrian environment data relating to traffic, walking, and environment for a surrounding area of the received location, and to collect dynamic data reflecting variation patterns accumulated over time;
a point derivation unit configured to derive, through time-series analysis based on the pedestrian environment data and the dynamic data, optimal pick-up and drop-off points within the surrounding area; and
a visualization unit configured to visualize the derived points and display them on the user terminal.

According to embodiments of the present invention, by performing time-series analysis on transportation, walking, and environmental data, optimal pick-up and drop-off points can be derived that are dynamically optimized according to varying factors such as time of day, weather, and traffic congestion. Consequently, all pedestrians can select safe and efficient travel routes suited to their situational conditions.

According to embodiments of the present invention, by considering both disability-type conditions (e.g., for visually impaired persons, persons with physical disabilities, or elderly persons) and pedestrian environment conditions (e.g., illumination, ramps, obstacles, etc.), the system can prioritize pick-up and drop-off points and visualize the results. As a result, transfer accessibility among transportation modes is improved and travel inconvenience can be minimized.

According to embodiments of the present invention, by linking with an urban real-time traffic and pedestrian control system, design and operational information of mobility points (MPs) can be integrated and managed with the overall urban mobility infrastructure, thereby enabling sustainable expansion of smart mobility infrastructure at the city level.

However, the effects of the present invention are not limited to those described above, and various other effects may be achieved without departing from the spirit and scope of the present invention.

### BRIEF DESCRIPTION OF THE DRAWINGS

These and/or other aspects, features, and advantages of the invention will become apparent and more readily appreciated from the following description of embodiments, taken in conjunction with the accompanying drawings of which:

FIG. 1 is a schematic block diagram illustrating a configuration in which a mobility point design system based on time-series analysis, according to an embodiment of the present invention, is linked with an external control system.

FIG. 2 is a block diagram illustrating detailed components of the mobility point design system based on time-series analysis according to an embodiment of the present invention.

FIG. 3 is a flowchart illustrating an operational flow of a mobility point design method based on time-series analysis according to an embodiment of the present invention.

FIG. 4 is a detailed flowchart illustrating the operations of step S330 according to an embodiment of the present invention.

FIG. 5 is a detailed structural diagram illustrating data construction and platform implementation of the mobility point design system based on time-series analysis according to an embodiment of the present invention.

FIG. 6 is an example view illustrating visualization information of mobility points (MPs) according to an embodiment of the present invention.

### DETAILED DESCRIPTION

Hereinafter, example embodiments of the invention are described in detail with reference to the accompanying drawings, such that one of ordinary skill in the art to which the invention pertains may easily implement the invention. However, the invention may be implemented in various different forms and is not limited to the example embodiments described herein. In the drawings, parts that are irrelevant to the description are omitted to clearly describe the example embodiments.

The terms used herein are simply used to explain a specific example embodiment and are not construed as limiting the invention. The singular expression may include the plural expression unless the context clearly indicates otherwise.

It will be further understood that the terms “comprises” and/or “comprising,” when used in this specification, specify the presence of stated features, integers, steps, operations, elements, components, and/or combinations thereof, but do not preclude the presence or addition of one or more other features, integers, steps, operations, elements, components, and/or combinations thereof.

Also, components shown in example embodiments are independently illustrated to represent different characteristic functions and do not indicate that each of the components is implemented as separate hardware or a single software configuration unit. That is, each component is described by listing each component for clarity of description, and at least two components among the components may be integrated into a single component or a single component may be divided into a plurality of components, to perform a function. An integrated example embodiment and separate example embodiment of each component is also included in the scope of the invention as far as it does not depart from the spirit of the invention.

Also, the following example embodiments are provided to provide clearer explanation to one of ordinary skill in the art, and shapes and sizes of components in the drawings may be exaggerated for clearer explanation.

Hereinafter, example embodiments will be described with reference to the accompanying drawings.

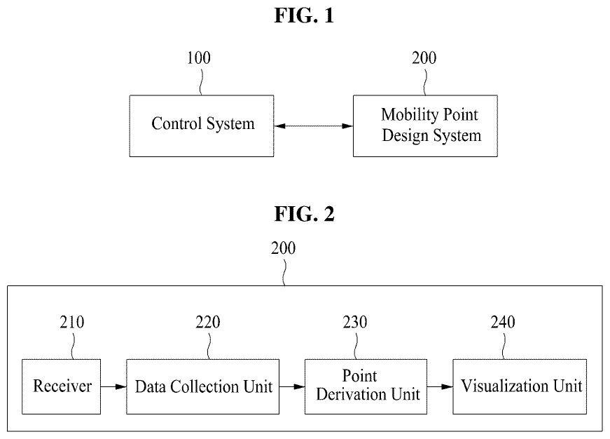

FIG. 1 is a schematic block diagram illustrating a configuration in which a mobility-point (MP) design system based on time-series analysis according to an embodiment of the present invention is linked with an external control system.

Referring to FIG. 1, the mobility-point design system 200 based on time-series analysis according to the embodiment of the present invention is communicably connected to a control system 100 that manages urban transportation, walking, and environmental data, performs time-series analysis based on real-time pedestrian-environment data received from the control system 100, and functions to design and recommend pick-up and drop-off points according to the analysis results.

The control system 100 may include a transportation control platform that manages real-time bus and subway locations, an urban infrastructure-management system that collects data such as road conditions, construction, and weather, and a smart-city control center that integrally manages pedestrian-safety and IoT sensors. The control system 100 may include pedestrian-environment data and real-time dynamic data collected from urban-infrastructure sensors, transportation networks, CCTVs, weather databases, and a GIS (Geographic Information System), and by providing this data to the mobility-point design system 200, it is possible to improve the accuracy of design and operation of mobility points (MPs).

Here, the pedestrian-environment data may include static spatial data such as road width, gradient, crosswalk location, and tactile-paving position calculated from spatial data on the GIS, while the dynamic data may include time-varying data such as traffic volume, pedestrian density, weather, illumination, and road-construction status.

Meanwhile, the mobility-point design system 200 based on time-series analysis according to an embodiment of the present invention may be implemented as an integrated pedestrian-navigation service supporting the movement of all pedestrians, including mobility-vulnerable persons, in the form of an application running on a user (or pedestrian) terminal. The terminal may be any of a smart phone, mobile phone, tablet PC, navigation device, or user-wearable device (vibration device or wearable device).

The mobility-point design system 200 based on time-series analysis according to an embodiment of the present invention may be a substitute MP recommendation system that utilizes GIS-based pedestrian-environment data and dynamic data together with a machine-learning model to reflect the results of pedestrian-safety and mobility-point usability analysis. The system 200 analyzes the user's movement patterns to evaluate MP accessibility, obstacles, walkway width, and gradient, and provides customized MP candidates and routes according to user types (for example, general users, elderly people, or persons with disabilities), thereby designing drop zones, pick-up zones, and transfer zones linked with road and public-transport infrastructure.

More specifically, when a user inputs either a departure point or a destination, the mobility-point design system 200 based on time-series analysis analyzes pedestrian-environment data, dynamic data, traffic congestion, and obstacle information to simultaneously calculate optimal pick-up and drop-off points and visually display their priorities according to accessibility, safety, and ease of movement. Additionally, the mobility-point design system 200 may update the movement routes and MP locations in real time according to pedestrian-environment data and real-time dynamic data received from the control system 100.

The mobility-point design system 200 based on time-series analysis according to an embodiment of the present invention may provide a personalized optimal route that reflects user type, spatial characteristics, and mobility means by utilizing the MP concept of integrated transport hubs where boarding, alighting, and transfers between various transport modes occur and AI-based route-setting algorithms.

Furthermore, the mobility-point design system 200 based on time-series analysis according to an embodiment of the present invention collects and analyzes real-time dynamic data to reflect changes in the pedestrian environment and traffic flow within MPs, interlocks with the control system 100 to secure data reliability through quantitative analysis and systematic verification, and maximizes user mobility convenience.

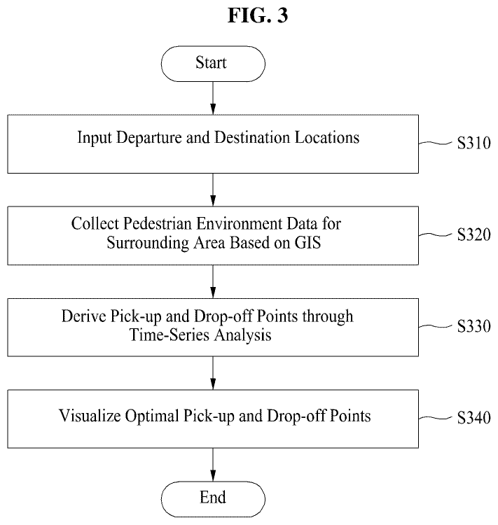

FIG. 2 is a block diagram illustrating detailed components of the mobility-point design system based on time-series analysis according to an embodiment of the present invention,

FIG. 3 is a flowchart illustrating the operation flow of the mobility-point design method based on time-series analysis according to an embodiment of the present invention, and

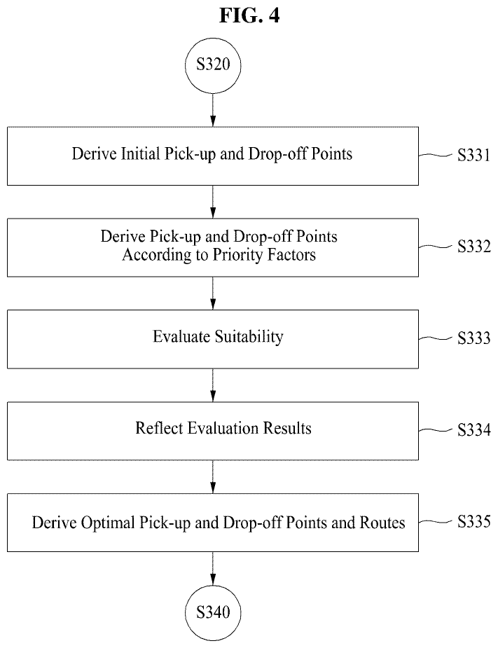

FIG. 4 is a detailed flowchart illustrating the operations of step S330 according to an embodiment of the present invention.

In the embodiments of the present invention, a computer device may perform the mobility-point design method based on time-series analysis to design and provide pick-up and drop-off points.

To this end, the computer device may include a mobility-point design system 200 based on time-series analysis, which serves as the subject that performs the method.

For example, the mobility-point design system 200 based on time-series analysis may be implemented as an independently operating program or may be configured in an in-app form of a dedicated application so that it can operate within the dedicated application.

The processor of the computer device may be implemented as a component for performing the mobility-point design method based on time-series analysis according to FIGS. 3 and 4.

For example, as shown in FIG. 2, the processor may include a receiver 210, a data-collection unit 220, a point-derivation unit 230, and a visualization unit 240 to perform the steps S310 to S340 shown in FIGS. 3 and 4.

Depending on the embodiment, the components of the processor may be selectively included or excluded, or may be separated or combined to represent processor functions.

The processor and its components may control the computer device to perform the steps S310 to S340 included in the mobility-point design method based on time-series analysis shown in FIGS. 3 and 4.

For example, the processor and its components may be implemented to execute instructions according to the codes of the operating system and at least one program contained in memory.

Here, the components of the processor may represent different functions performed by the processor according to the commands provided by the program code stored in the computer device.

The processor may read necessary instructions from memory in which commands related to the control of the computer device are loaded.

In this case, the read instructions may include commands for controlling the processor to execute the steps S310 to S340 described below.

The subsequent steps S310 to S340 may be performed in an order different from that illustrated in FIGS. 3 and 4, and some of the steps may be omitted or additional processes may be included.

Referring to FIGS. 2 and 3, in step S310, the receiver 210 receives either a departure point or a destination from a user terminal.

The receiver 210 may receive user information including a disability type of the user such as visual, physical, or hearing impairment, or whether the user is elderly.

In addition, the receiver 210 may receive the current location of the user or both the departure and destination locations.

For example, the user may, through an application or web interface using a terminal they possess, select their disability type (visual, physical, or hearing impairment), mobility aid (wheelchair, white cane for visually impaired, etc.), or elderly status (65 years or older), and input departure and destination; the receiver 210 receives and transfers the information input by the user.

In step S320, the data-collection unit 220 collects pedestrian-environment data relating to traffic, walking, and environment for the surrounding area of the input location (departure or destination), and dynamic data reflecting variation patterns accumulated over time.

The data-collection unit 220 may refer to multi-layered static spatial data centered on the input location (departure or destination) on a Geographic Information System (GIS) to obtain pedestrian-environment data including traffic, walking, and environmental data.

More specifically, the pedestrian-environment data may include traffic data such as vehicle volume, signal position, signal cycle, and road type; walking data including at least one of road width, crosswalk position, signal cycle, tactile-paving position, presence of ramps, and rest-facility locations; and environmental data including at least one of weather, illumination, and road-surface condition.

In addition, the data-collection unit 220 may interlock with an external control system to receive not only static spatial data on the GIS but also real-time dynamic data such as changes in traffic volume, pedestrian density, and weather conditions.

Through this, the data-collection unit 220 may provide both the static spatial pedestrian-environment data and the dynamic environmental data as input data necessary for performing the time-series analysis of the subsequent step (step S330).

In step S330, the point-derivation unit 230 derives optimal pick-up and drop-off points within the surrounding area through time-series analysis based on the pedestrian-environment data and dynamic data.

At this time, the point-derivation unit 230 may derive, based on the input location (departure or destination), routes from the departure to pick-up points, from drop-off points to the destination, or from pick-up points to drop-off points simultaneously.

The data collection unit (110 of FIG. 1) collects static pedestrian environment data (e.g., road width, slope, sidewalk block type, fixed obstacle locations) as well as dynamic data, such as real-time traffic volume, pedestrian density, and weather conditions.

Additionally, the dynamic data may further include, as essential information for the movement of mobility-vulnerable persons, real-time operational status and malfunction information of mobility-assisting devices such as elevators and wheelchair lifts within public transportation facilities, real-time road construction information, or information on restricted areas due to public events or protests, which can be received in real-time from related public data APIs (Application Programming Interfaces) or IoT sensors.

The point-derivation unit (120) performs a time-series analysis by combining the collected static data and dynamic data. Specifically, the time-series analysis may utilize statistical models such as ARIMA (Autoregressive Integrated Moving Average), SARIMA (Seasonal ARIMA), or deep-learning models based on recurrent neural networks (RNNs) such as LSTM (Long Short-Term Memory) or GRU (Gated Recurrent Unit).

For example, an LSTM model may be used to predict pedestrian density or traffic congestion at a specific intersection during specific time periods (e.g., 8-10 AM commute time, 2-4 PM on weekends), and this prediction can be reflected as a weight when deriving the initial mobility points (MPs).

Tthe point-derivation unit (120) analyzes image data near the pick-up and drop-off points using AI deep-learning-based object-detection technology and automatically identifies obstacles, facilities, and pedestrian environments.

This object-detection technology may be based on, for example, deep learning models in the YOLO (You Only Look Once) series (e.g., YOLOv8), which excel in real-time processing, SSD (Single Shot MultiBox Detector), or the Faster R-CNN series, which is known for high accuracy.

The point-derivation unit (120) assigns priority scores (or factors) to each derived initial point by reflecting one or more of disability-type conditions and pedestrian-environment conditions.

The method for calculating this priority score may have various embodiments.

In a first embodiment, the score may be calculated by summing weights based on a predefined weighted lookup table. For example, when evaluating a point for a wheelchair user, weights may be assigned according to the importance of each condition: ‘sidewalk effective width 1.5 m or more’ (+10 points), ‘access route slope less than 5%’ (+10 points), ‘no curb (or curb <2 cm)’ (+20 points), and ‘elevator proximity within 50 m’ (+15 points), and the total score is then calculated.

In a second embodiment, a machine-learning regression model (e.g., Random Forest, Gradient Boosting) may be used. In this case, the disability-type conditions and pedestrian-environment conditions (e.g., width, slope, number of obstacles, illumination) are used as multiple input features, and satisfaction ratings (e.g., 1-5 points) evaluated by actual mobility-vulnerable users are used as labels to train the model, which then derives a priority score (e.g., 0-100 points).

The model is pre-trained on an extensive training dataset comprising 30 or more classes of obstacles and facilities, including ‘curbs’, ‘stairs’, ‘ramps’, ‘bollards’, ‘tactile paving’ (braille blocks), ‘manholes’, ‘illegally parked vehicles’, and ‘temporary obstacles’ (e.g., signboards).

Based on the analysis results, when evaluating a point for a wheelchair user, if a curb higher than 5 cm is detected on the access route to the point, or if the effective slope of a ramp exceeds 8%, the point-derivation unit (120) may evaluate the suitability of the point as ‘unsuitable’ or assign a ‘risk’ rating, thereby lowering its priority score.

More specifically, referring to FIG. 3, in step S331 of step S330 according to the embodiment of the present invention, the point-derivation unit 230 may combine the pedestrian-environment data with dynamic data reflecting variation patterns accumulated over time and derive initial pick-up and drop-off points (first-stage points) through time-series analysis.

Here, the time-series analysis used in the present invention is not merely arranging data collected at a specific point in time, but an analytical technique for predicting future states or deriving temporal correlations by analyzing patterns (trends, periodicities, fluctuations, etc.) of data changing over time.

Unlike static data analysis at a single time point, time-series analysis reflects real-time factors such as time of day, day of week, season, weather, traffic congestion, and pedestrian density, learns variability of data, and can predict trends at future times based on the results.

Accordingly, in the embodiment of the present invention, the time-series analysis technique is utilized to analyze patterns of pedestrian-environment data that change with time, weather, traffic volume, and pedestrian congestion in the area surrounding the input location, and to dynamically optimize pick-up and drop-off points based on the analyzed results.

In addition, the real-time dynamic data refers to data accumulated at fixed time intervals including traffic volume, pedestrian density, weather, illumination, and road-construction status, received from the control system in real time, meaning time-series data reflecting variation patterns by hour, day, and season.

Accordingly, the point-derivation unit 230 may combine the pedestrian-environment data and the real-time dynamic data reflecting variation patterns accumulated over time, provided from the data-collection unit 220, to derive pick-up and drop-off points through time-series analysis.

By performing time-series analysis reflecting real-time factors such as time, day, weather, traffic congestion, and pedestrian density, the point-derivation unit 230 can predict accessibility and safety levels of the surrounding area of the input location (departure or destination).

The point-derivation unit 230 may derive pick-up and drop-off points along the travel route from the current user location to the destination in the order of highest accessibility and safety based on the results of the time-series analysis.

For example, when the user inputs a destination, the point-derivation unit 230 may, among a plurality of travel routes from the current location to the destination, derive pick-up points for boarding transportation means and drop-off points for starting pedestrian movement after alighting, by comprehensively considering traffic congestion, pedestrian accessibility, existence of obstacles, and environmental factors, and may derive them in the order of highest accessibility and safety (for example, first to fifth priorities).

In step S332, the point-derivation unit 230 assigns priority scores to each initial point (first-stage point) by reflecting one or more of disability-type conditions and pedestrian-environment conditions and derives pick-up and drop-off points (second-stage points) according to priority factors.

The point-derivation unit 230 calculates priority scores for each of the plurality of initial pick-up and drop-off points (first-stage points) derived based on the time-series analysis and applies weighting to reflect priority.

The priority calculation is performed by evaluating one or more of the disability-type conditions and pedestrian-environment conditions.

The evaluation of disability-type conditions may calculate accessibility and safety from static obstacles, situational obstacles, and facility information according to user type such as disability type (visual, physical, hearing) or whether the user is elderly (65 or older) and reflect the weighting corresponding to the evaluation results in the priority score.

Here, the static obstacles include walkway loss/damage, curbs, bollards, driveway entrances, drainage grates, speed bumps, and other facilities; the situational obstacles include obstructing vehicles, construction zones, signboards, trash piles, tables, stalls, other hindrances, icing, flooding, ground heat, fine dust, shadows, and diseases; and the facility information includes stairs, ticket gates, lifts (wheelchair lifts), information desks, entrances, and platforms.

The evaluation of pedestrian-environment conditions may use one or more of weather, time of day, traffic congestion, selected transportation mode (subway, bus, autonomous shuttle, walking, etc.), walkway width, road-construction status, and seasonal factors to evaluate mobility convenience in the current environment and reflect the weighting according to the evaluation results in the priority score.

At this time, the point-derivation unit 230 may personalize the derived pick-up and drop-off points and travel routes by reflecting the user's movement characteristics and preferences.

For example, the user may pre-input personalized movement preferences such as “avoid stairs,” “minimize crosswalks,” or “prefer ramps” through the settings screen of the terminal, and the point-derivation unit 230 may reflect walking preferences as priority scores in the evaluation of pedestrian-environment conditions.

Accordingly, among the initial candidates (first-stage points), the point-derivation unit 230 applies weighted priority scores according to disability-type and pedestrian-environment conditions to generate a more realistic and situationally adaptive second-stage candidate set.

For example, for visually impaired users, continuity of tactile paving and the presence of audible traffic signals have high weights; for physically disabled users, the presence of ramps, road-level differences, and wheelchair accessibility are primarily considered; and for elderly users, walkway width, proximity to rest facilities, and illumination are important evaluation elements.

When an integrated transportation mode such as subway and bus is selected, transfer convenience, transfer time, and transfer distance of the pick-up and drop-off points are primarily considered.

In step S333, the point-derivation unit 230 may utilize AI deep-learning-based object-detection technology to analyze image data around the pick-up and drop-off points and evaluate their suitability by automatically identifying obstacles, facilities, and walkway structures.

The point-derivation unit 230 may analyze image data near the derived pick-up and drop-off points (second-stage points) using AI deep-learning-based object-detection technology.

In this process, it automatically identifies obstacles, facilities, and walkway structures composing the pedestrian environment and, based on the position, shape, and distance information of each object, evaluates whether the point is actually a location that is safe and accessible for the user (the second-stage point).

More specifically, the point-derivation unit 230 may identify the presence of obstacles such as tactile paving, curbs, construction fences, or road signs through image analysis and calculate the distance between each obstacle and the user's expected walking path, thereby assigning a danger or warning level to the point.

For example, if the distance from an obstacle is close (e.g., 1 m or less) or the slope is steep, it is evaluated as a “Danger” level; if the distance from an obstacle is moderate (e.g., 2-3 m) and caution is required for accessibility, it is evaluated as a “Warning” level; and if there is no obstacle or the walking path is clear, it is evaluated as a “Safe” level.

In step S334, the point-derivation unit 230 recognizes risk factors around the pick-up and drop-off points based on the evaluation results and may reflect the recognized risk factors.

The point-derivation unit 230 recognizes the risk factors around the pick-up and drop-off points (second-stage points) based on the evaluation results and, depending on the recognized risk factors, may correct or optimize the walking path, that is, generate detour routes.

At this time, considering the user's mobility characteristics (for example, wheelchair accessibility, walkway gradient, illumination, etc.), it may propose alternative points with lower risk and higher movement efficiency.

In addition, the AI-based evaluation results may be interlocked with the GIS-based spatial database so that risk levels, obstacle information, and safety grades are updated in a time-series manner.

Accordingly, the point-derivation unit 230 can reflect pedestrian-environment changes over time and correct and optimize dynamic safe paths around the pick-up and drop-off points (second-stage points) in real time.

In step S335, the point-derivation unit 230 may derive the optimal pick-up and drop-off points (third-stage points) and optimize the paths to the optimally derived points.

The point-derivation unit 230 may finally derive optimal pick-up and drop-off points (third-stage points) that have been verified for stability, accessibility, and environmental adaptability through the suitability evaluations (steps S333 and S334).

At this time, the point-derivation unit 230 integrates the risk-evaluation results of the second-stage points with the priority scores weighted by disability-type and pedestrian-environment conditions, calculates a comprehensive score for each point, and determines the point with the maximum score as the optimal pick-up and drop-off point.

However, depending on the embodiment, a second-stage point may be determined as a third-stage point.

In addition, the point-derivation unit 230 analyzes the spatial relationship among the derived third-stage points (optimal pick-up and drop-off points) and the pedestrian network (connection nodes on the GIS) to optimize the route from the user's current location to the corresponding point.

For example, the point-derivation unit 230 may avoid sections marked “Danger” in the path from the user's location to the pick-up point and re-search an alternative path including only “Safe” or “Warning” levels, thereby calculating a minimum-risk path (Safe-Optimized Path).

Among paths of the same safety grade, it may evaluate route efficiency based on travel distance and estimated travel time and select the final route.

Furthermore, the point-derivation unit 230 according to the embodiment of the present invention may periodically update the optimal movement routes and pick-up and drop-off points.

The point-derivation unit 230 may analyze walkway data (width, slope, and surface condition) based on the pedestrian path, record obstacle and facility information as image and coordinate data, and integrate them into the GIS-based database.

In step S340, the visualization unit 240 visualizes the derived points and displays them on the user terminal.

The visualization unit 240 may display the derived optimal pick-up and drop-off points (third-stage points) on the user terminal using different visual identifiers such as blue, green, or yellow, according to priority factors.

The visualization unit 240 may indicate pick-up and drop-off points using blue, green, or yellow flags based on disability type (visual impairment, physical impairment, or elderly) or situational conditions (weather, traffic complexity, existence of obstacles on the route, season, time such as morning/evening, and walkway congestion).

For example, the visualization unit 240 may provide blue points (pick-up and drop-off points) for physically disabled users, green points for elderly users, and yellow points for times of high traffic or walkway congestion.

At this time, the visualization unit 240 may display visual elements such as icons, scores, and route lines corresponding to each color, and the user may select the point on the terminal screen to check detailed information (for example, route, estimated travel time, obstacle information, and safety score).

In addition, the visualization unit 240 may provide voice and vibration guidance according to the user's disability type through the user's terminal.

For example, for visually impaired users, voice guidance through TTS (Text-to-Speech) and vibration guidance may be provided; for hearing-impaired users, vibration and subtitle display may be provided; and for physically disabled users, vibration warnings or text alerts before entering obstacle sections (such as curbs or stairs) may be provided.

In this case, vibration guidance may be provided through the terminal held by the user or through a vibration device worn on a part of the user's body such as the wrist or neck, connected with the terminal.

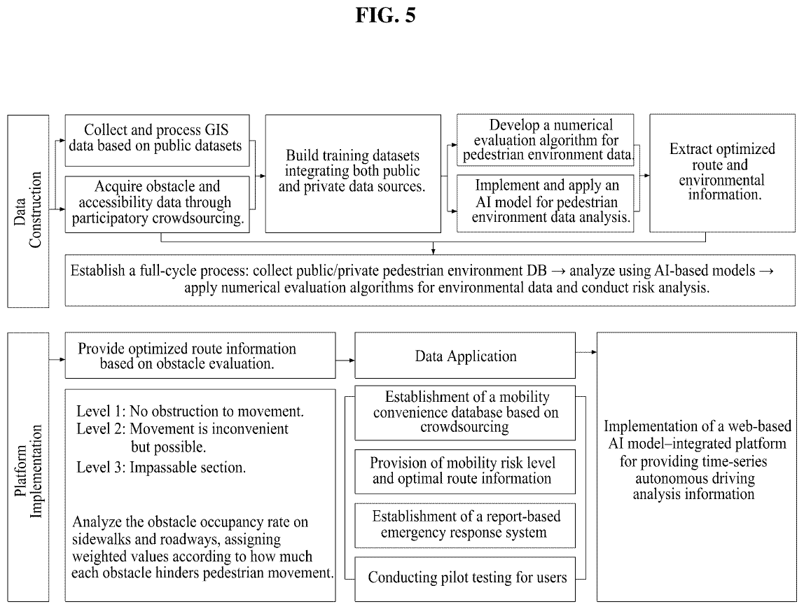

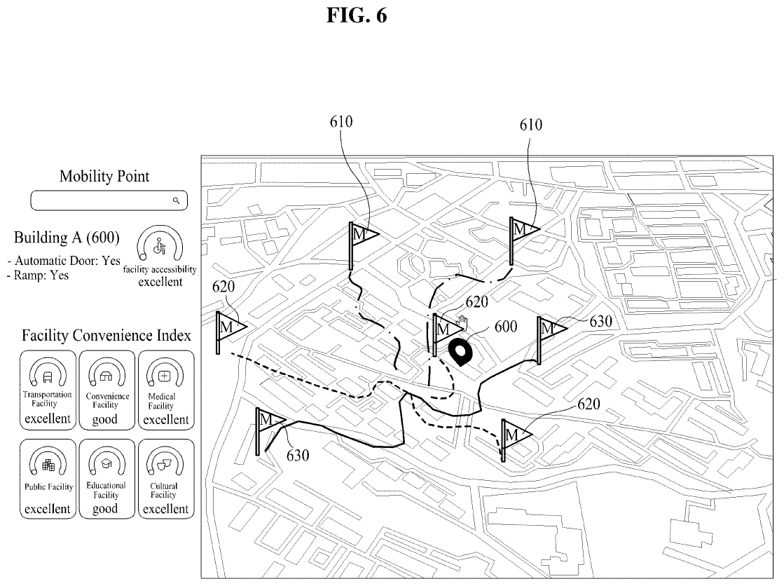

FIG. 5 is a detailed structural diagram illustrating data construction and platform implementation of the mobility-point design system based on time-series analysis according to an embodiment of the present invention, and FIG. 6 is an example view illustrating visualization information of mobility points (MPs) according to an embodiment of the present invention.

Referring to FIG. 5, the mobility-point design system according to an embodiment of the present invention constructs a GIS-based pedestrian-environment database by utilizing public and private data, collects real-time dynamic data through the control system and crowdsourcing, and converts it into a training dataset to develop a pedestrian-environment evaluation algorithm.

Thereafter, an AI-based time-series analysis model is applied to evaluate risk level, accessibility, and safety of the pedestrian environment, and based on the evaluation results, optimal pick-up and drop-off points are derived while the route information is implemented to be updated in real time at the platform level.

The mobility-point design system according to an embodiment of the present invention may, when a user inputs a destination or departure point, derive a plurality of pick-up and drop-off points around the corresponding location through time-series analysis and visually display them on a map-based interface.

FIG. 6 shows an example in which pick-up points (610, 620, 630) are visually displayed when a user has entered a destination (600).

Referring to FIG. 6, a plurality of derived points may be displayed on the map screen distinguished by different colors or shapes.

For example, a blue flag (610) represents the first-priority recommended point (pick-up point) with the highest accessibility and safety, a green flag (620) represents the second-priority point (pick-up point) with good accessibility and safety, and a yellow flag (630) represents the third-priority point (pick-up point) that requires relative caution.

In addition, color classification may be set according to one or more criteria depending on situations.

For example, in the case of recommendation based on priority by disability type, the blue flag (610) represents a point suitable for visually impaired users (including continuity of tactile paving and presence of audible signals), the green flag (620) represents a point suitable for physically impaired users (including ramps, level-free sections, and elevators), and the yellow flag (630) represents a point suitable for elderly users (adjacent to rest facilities, gentle slopes, shortest distance).

As another example, in the case of recommendation based on priority by environmental conditions, the blue flag (610) represents a point most preferably recommended under the current time and environmental conditions, the green flag (620) represents a point with good pedestrian accessibility but some environmental constraints, and the yellow flag (630) represents a point temporarily not recommended for use due to current environmental factors (for example, traffic congestion, obstacle occurrence, or reduced nighttime illumination).

However, the priority based on color is not limited to the above examples and may be dynamically changed according to various factors such as user type, pedestrian environment, traffic situation, time of day, and weather conditions.

In particular, the mobility-point design system according to an embodiment of the present invention may visualize real-time point priority according to environmental conditions that change over time by switching in real time at least one of the colors blue, green, and yellow according to the results of time-series analysis.

In addition, the left area of FIG. 6 shows an example of a mobility-point (MP) information-display interface (UI) implemented on the user-terminal screen by the visualization unit according to an embodiment of the present invention.

This interface may visually provide movement information and facility-convenience information around the destination input by the user (for example, building A (600)).

More specifically, in the search-box area at the top, the user may input the destination or enter the name of a major building or facility accessible from the current location.

In this example, “Building A (600)” is displayed as selected, and below it facility-accessibility information such as “automatic door: yes” and “ramp: yes” may be provided together.

This function enables users using wheelchairs or walking aids to immediately check whether the destination building structure is accessible.

Below that, a facility convenience index is displayed.

This index quantifies and visually presents accessibility and convenience of use for major living-related facilities around the destination (for example, transportation, amenities, medical, public, educational, and cultural facilities).

However, although FIG. 6 illustrates a plurality of pick-up points (610, 620, 630) for the destination (600) as an example, the mobility-point design system according to the embodiment of the present invention is not limited thereto and may visualize a plurality of drop-off points for the destination (600).

In addition, the user may input a departure point instead of a destination, and the mobility-point design system according to the embodiment of the present invention may visualize a plurality of pick-up and drop-off points corresponding to the departure point.

Furthermore, when transfers between a plurality of transportation modes occur, the mobility-point design system according to the embodiment of the present invention may additionally derive and visualize transfer points corresponding to the movement sections between the transportation modes.

The system or apparatus described above may be implemented using hardware components, software components, or combinations thereof.

For example, the apparatus and components described in the embodiments may be implemented using one or more general-purpose or special-purpose computers such as processors, controllers, arithmetic-logic units (ALUs), digital-signal processors (DSPs), microcomputers, FPGAs (Field-Programmable Gate Arrays), PLUs (Programmable Logic Units), microprocessors, or other devices capable of executing and responding to instructions.

A processing device may execute one or more software applications on an operating system (OS) and may access, store, manipulate, process, and generate data in response to software execution.

Although described for convenience as employing a single processor, those skilled in the art will recognize that the processing device may include multiple processing elements and/or multiple types of processing elements (e.g., a processor and a controller, or parallel processors).

Software may include computer programs, code, instructions, or combinations thereof configured to cause the processing device to perform desired operations.

The software and/or data may be embodied, permanently or temporarily, in any type of machine, component, physical or virtual device, computer-storage medium, or transmitted signal that provides instructions or data interpretable by the processing device.

Software may also be distributed across network-connected computer systems so as to be stored or executed in a distributed manner.

Software and data may be stored in one or more computer-readable recording media.

The method according to the embodiment may be implemented as program instructions executable by various computer means and recorded on a computer-readable medium.

The computer-readable medium may include program instructions, data files, and data structures individually or in combination.

The program instructions may include those specially designed and configured for the embodiment or those known and available to software developers.

Examples of computer-readable storage media include ROM, PROM, EPROM, EEPROM, flash memory (e.g., NAND/NOR), SSDs, HDDs, magnetic tape, optical recording media (CD-ROM, DVD, BD), magneto-optical media, memory cards, and USB memories.

The storage medium is non-transitory and does not include pure transmission signals or purely volatile memory such as RAM.

Although the embodiments have been described with reference to limited examples and drawings, those skilled in the art will appreciate that various modifications and alterations can be made from the foregoing description.

For example, the described techniques may be executed in an order different from that described, and the systems, structures, devices, and circuits described may be combined or replaced with other components or equivalents without departing from the intended results.

Accordingly, other implementations, embodiments, and equivalents fall within the scope of the following claims.

What is claimed is:

1. A method for designing mobility points based on time-series analysis, performed by a computer device including at least one processor, the method comprising:
receiving, from a user terminal, one of a departure point and a destination;
collecting, for a surrounding area of the received location, pedestrian-environment data relating to traffic, walking, and environment, and dynamic data reflecting variation patterns accumulated over time;
deriving, through time-series analysis based on the pedestrian-environment data and the dynamic data, optimal pick-up and drop-off points within the surrounding area; and
visualizing the derived points and displaying them on the user terminal.

2. The method according to claim 1,
wherein the receiving step further comprises receiving, from the user, user information including a disability type of the user-selected from visual, physical, or hearing impairment—or whether the user is elderly.

3. The method according to claim 1,
wherein the collecting of the pedestrian-environment data comprises collecting, from multi-layer spatial data of a geographic information system (GIS) centered on the received location, pedestrian-environment data including traffic data, walking data, and environmental data.

4. The method according to claim 3,
wherein the collecting of the pedestrian-environment data further comprises collecting, from an external control system, real-time dynamic data including traffic-volume variation, pedestrian density, and weather condition.

5. The method according to claim 4,
wherein the deriving of the pick-up and drop-off points comprises combining the pedestrian-environment data with the dynamic data reflecting variation patterns accumulated over time and deriving initial pick-up and drop-off points through time-series analysis.

6. The method according to claim 5,
wherein the deriving of the pick-up and drop-off points further comprises assigning priority scores to each of the derived initial points by reflecting one or more of disability-type conditions and pedestrian-environment conditions, and deriving pick-up and drop-off points according to priority factors.

7. The method according to claim 6,
wherein the deriving of the pick-up and drop-off points comprises evaluating disability-type conditions by determining accessibility and safety from static obstacles, situational obstacles, and facility information according to a user type including disability type or elderly status, and applying weighted values corresponding to the evaluation results to the priority score.

8. The method according to claim 6,
wherein the deriving of the pick-up and drop-off points comprises evaluating pedestrian-environment conditions based on at least one piece of information among weather, time of day, traffic congestion, walkway width, road-construction status, and seasonal factors, and applying weighted values corresponding to the evaluation results to the priority score.

9. The method according to claim 6,
wherein the deriving of the pick-up and drop-off points further comprises analyzing image data near the pick-up and drop-off points using AI deep-learning-based object-detection technology, and automatically identifying obstacles, facilities, and walkway structures from the analysis results to evaluate suitability of the pick-up and drop-off points.

10. The method according to claim 9,
wherein the deriving of the pick-up and drop-off points further comprises recognizing risk factors around the pick-up and drop-off points based on the evaluation results, and reflecting the recognized risk factors to optimize and derive the optimal pick-up and drop-off points and routes thereto.

11. The method according to claim 10,
wherein the displaying step comprises displaying, on the user terminal, the optimal pick-up and drop-off points in visually distinguishable manners including blue, green, or yellow colors according to the priority factors.

12. A system for designing mobility points based on time-series analysis, comprising:
a receiver configured to receive, from a user terminal, one of a departure point and a destination;
a data-collection unit configured to collect, for a surrounding area of the received location, pedestrian-environment data relating to traffic, walking, and environment, and dynamic data reflecting variation patterns accumulated over time;
a point-derivation unit configured to derive, through time-series analysis based on the pedestrian-environment data and the dynamic data, optimal pick-up and drop-off points within the surrounding area; and
a visualization unit configured to visualize the derived points and display them on the user terminal.

13. The system according to claim 12,
wherein the receiver is further configured to receive, from the user, user information including a disability type of the user—selected from visual, physical, or hearing impairment—or whether the user is elderly.

14. The system according to claim 12,
wherein the data-collection unit is configured to obtain, from multi-layer spatial data of a geographic information system (GIS) centered on the received location, pedestrian-environment data including traffic data, walking data, and environmental data, and to collect, from an external control system, real-time dynamic data including traffic-volume variation, pedestrian density, and weather condition.

15. The system according to claim 14,
wherein the point-derivation unit is configured to combine the pedestrian-environment data with the dynamic data reflecting variation patterns accumulated over time to derive initial pick-up and drop-off points through time-series analysis, to assign priority scores to each of the derived initial points by reflecting one or more of disability-type conditions and pedestrian-environment conditions, and to derive optimal pick-up and drop-off points according to the priority factors.

16. The system according to claim 15,
wherein the point-derivation unit is configured to analyze image data near the pick-up and drop-off points using AI deep-learning-based object-detection technology and to automatically identify obstacles, facilities, and pedestrian environments from the analysis results to evaluate suitability of the pick-up and drop-off points.

17. The system according to claim 16,
wherein the point-derivation unit is configured to recognize risk factors around the pick-up and drop-off points based on the evaluation results, and to optimize and derive the optimal pick-up and drop-off points and routes thereto by reflecting the recognized risk factors.

18. The system according to claim 17,
wherein the visualization unit is configured to display, on the user terminal, the optimal pick-up and drop-off points in visually distinguishable manners including blue, green, or yellow colors according to the priority factors.
